(19) United States
(12) Patent Application Publication
(10) Pub. No.: US 2013/0049151 A1
(43) Pub. Date: Feb. 28, 2013

(54) ANODE-ILLUMINATED RADIATION DETECTOR

(71) Applicants: Vladimir A. Lobastov, Clifton Park, NY (US); Kevin Matthew Durocher, Waterford, NY (US); John Eric Tkaczyk, Delanson, NY (US); James Wilson Rose, Guilderland, NY (US); Paul Alan McConnelee, Albany, NY (US)

(72) Inventors: Vladimir A. Lobastov, Clifton Park, NY (US); Kevin Matthew Durocher, Waterford, NY (US); John Eric Tkaczyk, Delanson, NY (US); James Wilson Rose, Guilderland, NY (US); Paul Alan McConnelee, Albany, NY (US)

(73) Assignee: General Electric Company, Schenectady, NY (US)

(21) Appl. No.: 13/222,967

(22) Filed: Aug. 31, 2011

(51) Int. Cl. H01L 27/146; H01L 31/18

(52) U.S. Cl. 257/432; 438/66; 257/448; 257/E27.132; 257/E31.114

(57) ABSTRACT

Interconnect structures suitable for use in connecting anode-illuminated detector modules to downstream circuitry are disclosed. In certain embodiments, the interconnect structures are based on or include low atomic number or polymeric features and/or are formed at a density or thickness so as to minimize or reduce radiation attenuation by the interconnect structures.

### BACKGROUND

Non-invasive imaging technologies allow images of the internal structures of a subject (e.g., a patient or object) to be obtained without performing an invasive procedure on the patient or object. Non-invasive imaging systems may operate based on the transmission and detection of radiation through or from a subject of interest (e.g., a patient or article of manufacture). For example, X-ray based imaging techniques (such as mammography, fluoroscopy, computed tomography (CT), and so forth) typically utilize an external source of X-ray radiation that transmits X-rays through a subject and a detector disposed opposite the X-ray source that detects the X-rays transmitted through the subject. Other radiation based imaging approaches, such as positron emission tomography (PET) or single photon emission computed tomography (SPECT) may utilize a radiopharmaceutical that is administered to a patient and which results in the emission of gamma rays from locations within the patient's body. The emitted gamma rays are then detected and the gamma ray emissions localized.

Thus, in such radiation-based imaging approaches, the radiation detector is an integral part of the imaging process and allows the acquisition of the data used to generate the images of interest. In certain radiation detection schemes, the radiation may be detected by use of a scintillating material that converts the higher energy gamma ray or X-ray radiation to optical light photons (e.g., visible light), which can then be detected by photodetector devices, such as photodiodes. In other detection schemes, the X-ray or gamma ray energy may be directly converted to electrical signals in the detector apparatus, and these electrical signals are read-out electronically.

In certain of these direct conversion radiation detectors, the radiation passes through an electrode or other aspects of the detector packaging prior to reaching the sensor component of the detector. In such approaches, the packaging materials may attenuate the radiation being measured prior to the radiation reaching the sensor. In this manner, radiation signal may be lost to the sensor packaging, resulting on a loss or reduction of detector efficiency. As a result, to compensate for this lost signal, higher radiation doses may be employed to maintain the desired signal level reaching the sensing components of the detector.

### BRIEF DESCRIPTION

In accordance with one embodiment, a radiation detector is provided. The radiation detector comprises a plurality of detector elements comprising a direct conversion material that generates electrical signals directly in response to incident radiation. The radiation detector also comprises a respective anode for each detector element. Each anode is positioned over the respective detector element such that incident radiation passes through the anode before reaching the respective detector element. The radiation detector also comprises a flexible circuit structure comprising aluminum or copper interconnect pads in electrical contact with the anodes. The flexible circuit structure comprises one or more layers of a polymeric composition. The radiation detector also comprises an interconnect structure electrically connecting the respective anodes and the flexible circuit structure.

A method for forming a radiation detector is also provided. In accordance with one embodiment of the method, an aluminum or copper anode is formed on each of a plurality of detector elements. Each detector element comprises a direct conversion material that generates electrical signals directly in response to incident radiation. The respective anodes and respective aluminum or copper interconnect pads of a flexible circuit structure comprising one or more layers of a polymeric composition are electrically connected. The flexible circuit structure is electrically connected to readout circuitry suitable for acquiring signals from the plurality of detector elements.

In accordance with one embodiment, an imaging system is provided. The imaging system comprises a direct conversion radiation detector, a data acquisition system in communication with the radiation detector, and a controller controlling operation of the data acquisition system. The radiation detector comprises one or more detector modules. Each detector module comprises a plurality of detector elements that generates electrical signals directly in response to incident radiation; a flexible circuit structure comprising aluminum or copper interconnect pads each in electrical contact with an anode disposed in the radiation path of a respective detector element, wherein the flexible circuit structure comprises one or more layers of a polymeric composition; and an interconnect structure electrically connecting the respective anodes and the flexible circuit structure.

### BRIEF DESCRIPTION OF THE DRAWINGS

These and other features and aspects of embodiments of the present invention will become better understood when the following detailed description is read with reference to the accompanying drawings in which like characters represent like parts throughout the drawings, wherein:

FIG. 1 is a block diagram illustrating an embodiment of a general imaging system that may incorporate signal and/or data transmission, in accordance with an aspect of the present disclosure;

FIG. 2 is a block diagram illustrating an embodiment of an X-ray imaging system that may incorporate signal and/or data transmission, in accordance with an aspect of the present disclosure;

FIG. 3 is a block diagram illustrating an embodiment of a positron emission tomography/single photon emission computed tomography (PET/SPECT) imaging system that may incorporate signal and/or data transmission, in accordance with an aspect of the present disclosure;

FIG. 4 depicts a generalized layout of a detector module in accordance with an aspect of the present disclosure;

FIG. 5 depicts a schematic of generalized detector components including a mechanical substrate in accordance with an aspect of the present disclosure;

FIG. 6 depicts a schematic of generalized detector components including an interposer in accordance with an aspect of the present disclosure;

FIG. 7 depicts a plan-view of an anode-illuminated detector package in accordance with an aspect of the present disclosure;

FIG. 8 depicts a side-view of an anode-illuminated detector package in accordance with an aspect of the present disclosure;

FIG. 9 depicts a side-view of an anode-illuminated detector package including a collimator in accordance with an aspect of the present disclosure;

FIG. 10 depicts one embodiment of an interconnect structure between a flexible circuit and a sensor component in accordance with an aspect of the present disclosure;

FIG. 11 depicts another embodiment of the method for formation of interconnect structures between a flexible circuit and a sensor component in accordance with an aspect of the present disclosure;

FIG. 12 depicts a further embodiment of the method for formation of interconnect structures between a flexible circuit and a sensor component in accordance with an aspect of the present disclosure; and

FIG. 13 depicts an additional embodiment of the method for formation of interconnect structures between a flexible circuit and a sensor component in accordance with an aspect of the present disclosure.

### DETAILED DESCRIPTION

The present disclosure relates to the use of direct conversion detectors in radiation-based imaging applications. In a direct conversion detector, each radiation photon that is absorbed in the sensor material is converted to a number of electron-hole pairs in proportion to the energy of the radiation photon. A voltage applied across the thickness of the sensor drives the electrons to the anode and the holes to the cathode. Because the mobility of electrons is typically greater than holes in semiconductors with good radiation stopping power, the electron charge is collected on an array of anode electrodes. The electron charge is converted by read-out circuit to a digital imaging signal. The holes are collected on a cathode that is common to the whole sensor area and are not converted to an imaging signal. The anode pixel receiving the electrons is spatially correlated to the arrival position of each photon. Typically, the anode electrode is the pixel-array electrode and the cathode contact is a common electrode. The opposite arrangement, that is a pixel cathode, may be appropriate for other semiconductors where the hole signal is collected on an array of pixel cathodes and radiation incident to the cathode face.

In certain embodiments, the direct conversion detector is anode-illuminated (i.e., the X-rays or gamma rays passes through an anode-bearing surface of the detector before reaching the radiation sensing material or components of the detector). By illuminating the anode surface, the radiation is absorbed closer to the anode electrode and the electron signal is more readily collected. Faster response and less polarization may be achieved with this configuration. In such an embodiment, the radiation passes through an interconnect structure (such as a flexible or flex circuit and associated conductive contacts) which may attenuate the radiation before reaching the sensor material. In certain implementations, the interconnect structures that route signals from the sensor elements (e.g., pixels) to the readout electronics are formed using polymeric materials, low atomic number materials, low density or reduced thickness structures, and so forth to reduce or minimize radiation attenuation attributable to the interconnect structures. For example, in certain implementations, thin metal contacts on the sensor material and/or flexible circuit can be formed using aluminum or copper, as opposed to nickel, gold, or silver. Likewise, a composite epoxy-type interconnect between the sensor material and the flexible circuit can be filled with electrically conductive graphite (or other suitable materials) as opposed to nickel, silver, or gold. Further, in other implementations the routing substrate (e.g., flexible or flex circuit) may be formed using thin layers of a flexible polyimide (e.g., Kapton®) films and thin (15 μm-50 μm thick) plated copper traces. In yet further embodiments, laser-formed direct flex-trace to sensor contact interconnect structures may be employed as part of the contact structure. In such embodiments as these, radiation attenuation prior to the gamma rays or X-rays reaching the sensor material may be reduced relative to other anode-illuminated structures.

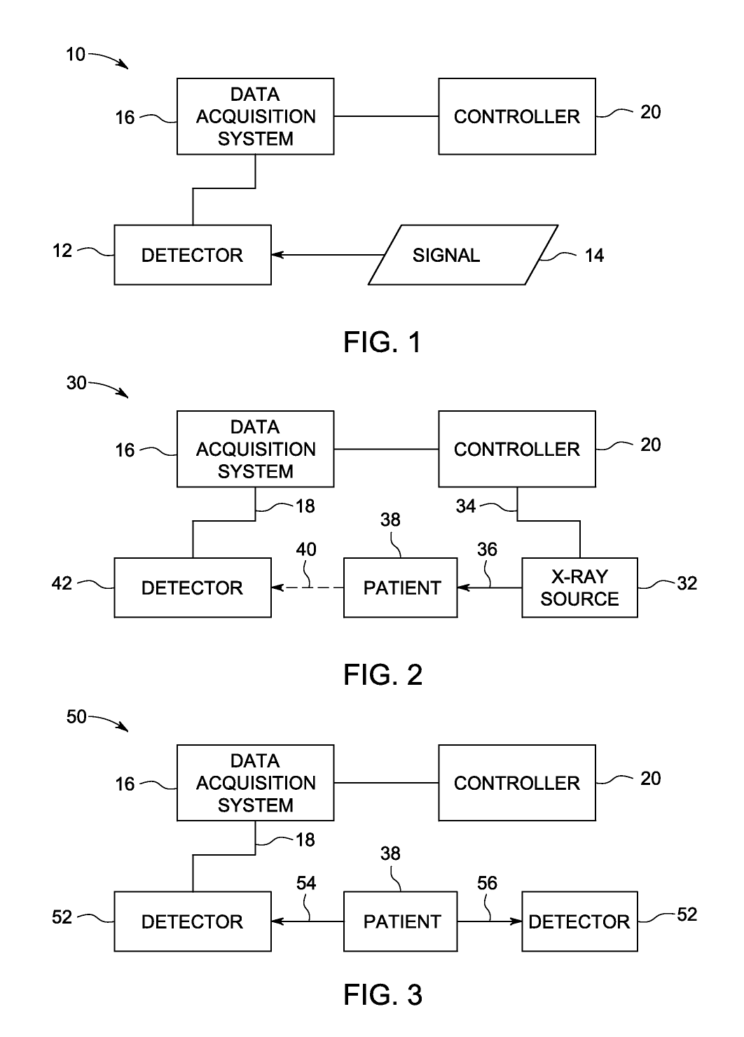

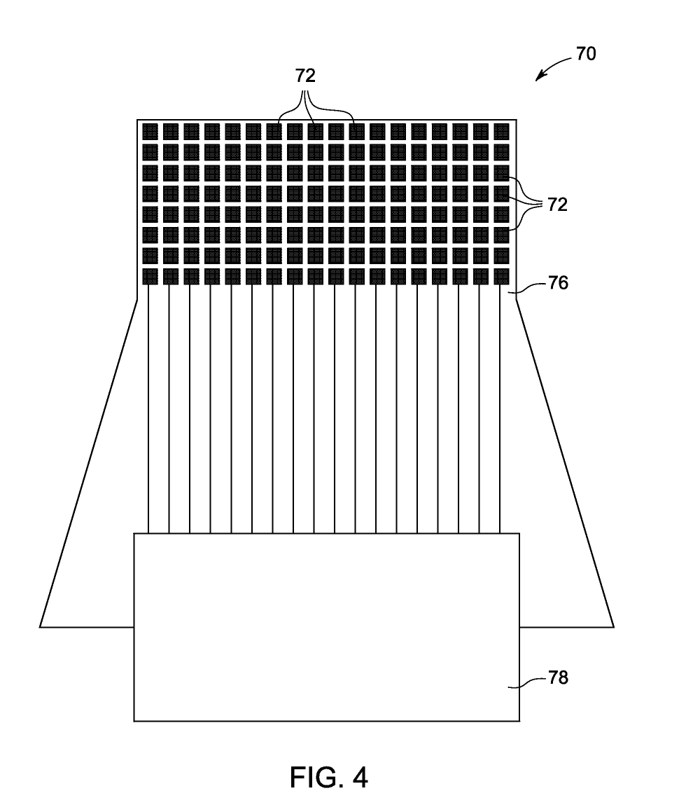

It should be noted that the present approaches may be utilized in a variety of imaging contexts, such as in medical imaging, product inspection for quality control, and for security inspection, to name a few. However, for simplicity, examples discussed herein relate generally to medical imaging, particularly radiation-based imaging techniques, such as: computed tomography (CT), mammography, tomosynthesis, C-arm angiography, conventional X-ray radiography, fluoroscopy, positron emission tomography (PET), and single-photon emission computed tomography (SPECT). However, it should be appreciated that these examples are merely illustrative and may be discussed merely to simplify explanation and to provide context for examples discussed herein. That is, the present approaches may be used in conjunction with any of the disclosed imaging technologies as well other suitable radiation-based approaches and in contexts other than medical imaging. Specifically, FIGS. 1-3 discuss embodiments of medical imaging systems that may utilize anode-illuminated direct conversion sensor packages, as discussed herein, with FIG. 1 being directed towards a general imaging system, FIG. 2 being directed towards an X-ray imaging system such as a CT/C-arm imaging system, and FIG. 3 being directed towards a PET/SPECT imaging system.

With the foregoing in mind, FIG. 1 provides a block diagram illustration of a generalized imaging system 10. The imaging system 10 includes a detector 12 for detecting a signal 14, such as emitted gamma rays or transmitted X-rays. The detector 12 may be a direct conversion type detector which directly generates electrical signals in response to incident radiation, i.e., without an intermediate conversion step by which the radiation is converted to another, lower-energy form, such as optical wavelengths. Generally, the more detection elements per unit of area in the detector 12, the greater its ability to spatially resolve such radiation, leading to higher quality images. In one embodiment, the signal 14 may pass through one or more packaging or structural features of the detector 12 (such as an anode and/or interconnect structure) before reaching the radiation sensing material of the detector 12. In such embodiments, and as discussed in greater detail below, the packaging and/or structural features may be composed of materials and/or may be otherwise configured to minimize or reduce attenuation of the signal 14, thereby allowing as much signal 14 as possible to be detected at the detector 12.

The detector 12 generates electrical signals in response to the detected radiation, and these electrical signals are sent through their respective channels to a data acquisition system (DAS) 16. Once the DAS 16 acquires the electrical signals, which may be analog signals, the DAS 16 may digitize or otherwise condition the data for easier processing. For example, the DAS 16 may filter the image data based on time (e.g., in a time series imaging routine), may filter the image data for noise or other image aberrations, and so on. The DAS 16 then provides the data to a controller 20 to which it is operatively connected. The controller 20 may be an application-specific or general purpose computer with appropriately configured software. The controller 20 may include computer circuitry configured to execute algorithms such as imaging protocols, data processing, diagnostic evaluation, and so forth. As an example, the controller 20 may direct the DAS 16 to perform image acquisition at certain times, to filter certain types of data, and the like. Additionally, the controller 20 may include features for interfacing with an operator, such as an Ethernet connection, an Internet connection, a wireless transceiver, a keyboard, a mouse, a trackball, a display, and so on.

Keeping such an approach in mind, FIG. 2 is a block diagram illustrating an embodiment of an X-ray imaging system 30 that may employ various features in accordance with the approaches noted above. The X-ray imaging system 30 may be an inspection system, such as for quality control, package screening, and safety screening, or may be a medical imaging system. In the illustrated embodiment, system 30 is an X-ray medical imaging system such as a CT or C-arm imaging system. In regards to the configuration of system 30, it may be similar in design to the generalized imaging system 10 described with respect to FIG. 1. For example, the system 30 includes the controller 20 operatively connected to the DAS 16, which allows the controlled acquisition of image data via an X-ray detecting array 42. In system 30, to enable the collection of image data, the controller 20 is also operatively connected to a source of X-rays 32, which may include one or more X-ray tubes.

The controller 20 may furnish a variety of control signals, such as timing signals, imaging sequences, and so forth to the X-ray source 32 via a control link 34. In some embodiments, the control link 34 may also furnish power, such as electrical power, to the X-ray source 32 via control link 34. Generally, the controller 20 will send a series of signals to the X-ray source 32 to begin the emission of X-rays 36, which are directed towards a subject of interest, such as a patient 38. Various features within the patient 38, such as tissues, bone, etc., will attenuate the incident X-rays 36. The attenuated X-rays 40, having passed through the patient 38, then strike the X-ray detecting array 42 to produce electrical signals representative of a corresponding data scan (i.e., an image). The X-ray detecting array 42 may be pixilated form discrete or pixilated detector elements such that hundreds or thousands of discrete detecting elements may be present on the X-ray detecting array 42. Each detecting element may correspond a single channel for data transmission.

In some imaging contexts, it can be important to transfer information that may be acquired substantially simultaneously, so as to correlate one acquired signal with another. One such imaging context is PET imaging systems, an embodiment of which is illustrated in FIG. 3. Specifically, FIG. 3 illustrates a block diagram of an embodiment of a PET imaging system 50 having a data link between a gamma ray detector array 52 and the DAS 16. In PET imaging, the detector 52 is generally configured to surround the patient 38. Specifically, the detector 52 of the PET system 50 may include a number of detector modules arranged in one or more rings about the imaging volume. For simplicity, the illustrated embodiment depicts two areas of the detector 52 disposed approximately 180 degrees apart so as to substantially simultaneously capture pairs of gamma rays that are emitted during imaging, as discussed below. It should be noted that in other embodiments, such as in SPECT embodiments, the detector 52 may be disposed as a ring, but a single, collimated photon is detected rather than a coincident photon pair as in PET.

The detector 52 detects photons generated from within the patient 38 by a decaying radionuclide. For example, a radionuclide may be injected into the patient 38 and may be selectively absorbed by certain tissues (e.g., tissues having abnormal characteristics such as a tumor). As the radionuclide decays, positrons are emitted. The positrons may collide with complementary electrons (e.g., from atoms within the tissue), which results in an annihilation event. The annihilation event, in PET, results in the emission of a first and second gamma photon 54, 56. The first and second gamma photons 54, 56 may strike the detectors 52 at separate areas approximately 180 degrees from one another. Typically, the first and second gamma photons 54, 56 strike the detectors 52 at approximately the same time (i.e., are coincident), and are correlated with one another. The origin of the annihilation event may then be localized. This is repeated for many annihilation events, which generally results in an image in which the contrast of the abnormal tissues appear enhanced. In this regard, it should be noted that the detector 52 may advantageously include a plurality of discrete detecting elements (e.g., pixilated elements) so as to allow high spatial resolution to produce an image of sufficient quality. For example, by detecting a number of gamma ray pairs, and calculating the corresponding lines traveled by these pairs, the concentration of the radioactive tracer in different parts of the body may be estimated and a tumor, thereby, may be detected. Therefore, accurate detection and localization of the gamma rays forms a fundamental and foremost objective of the PET system 50.

As noted above with respect to the generalized system of FIG. 1, in certain embodiments the X-ray detecting array 42 of the system of FIG. 2 or the gamma ray detector 52 of the system of FIG. 3 may be include packaging or structural features that act to attenuate the respective emitted or transmitted radiation prior to the radiation reaching the sensing material or components of the respective detectors. An example of such an embodiment may be an anode-illuminated implementation of a detector in which the an anode electrode and associated electrical interconnect structure are disposed on a surface of the detector facing the source of emission of the X-rays (FIG. 2) or gamma rays (FIG. 3). In accordance with aspects of the present disclosure, materials and/or structures are employed to minimize or otherwise reduce the attenuation of the respective radiation before the sensing material is reached.

Turning to FIG. 4, a generalized detector layout in accordance with the present disclosure is depicted. In the depicted layout, an example of a detector module 70 is provided. As will be appreciated, a detector 12, such as X-ray detector array 42 or gamma ray detector 52, may be formed from one or more such detector modules 70 situated so as to form a suitable radiation detection surface or array. In accordance with this example, a sensing portion of the detector module 70 includes an array of pixilated or otherwise discrete detector elements 72. In the depicted example the array of pixilated elements 72 is provided as an 8×16 array of pixels, with 128 pixels total.

Depending on the implementation, the detector elements may be based on cadmium telluride (CdTe), cadmium zinc telluride (CZT or CdZnTe), or any other suitable direct conversion radiation sensing material (such as gallium arsenide, mercury iodine, and so forth). Likewise, the contacts employed with the detecting elements 72 may be any suitable type, such as ohmic or blocking (i.e., Schottky) contacts. Further, as discussed herein, features or structures formed in or between the detecting elements may be scribed, deposited, chemically etched with lithographic masking or laser formed.

In addition to the detector elements 72 that perform the sensing of incident radiation, the depicted detector module 70 includes structural features and/or signal readout components that support or utilize the functionality of the detector elements 72. For example in the depicted example, the detector elements 72 may be positioned on or connected to an interconnect structure 76 (such as a printed circuit board, multilayered ceramics and/or flex circuit backing) that provides structural support for the detector elements and/or may also provide a substrate for the electrical interconnections that allow readout or operation of the detector elements 72.

The structural features and/or electrical interconnections may be described or defined as the package or detector package and various package options may be available, depending on the implementation. For example, package options may include the presence or use of a flex circuit having a suitable pitch or thickness. By way of example, a single layer flex circuit suitable for use with a 128 channels (i.e., one channel per pixilated detector element in the above example) may have a 50 μm pitch and corresponding electrical traces or connections for each channel. Conversely, a multi-layer flex circuit suitable for use with more detector elements (i.e., more channels, such as 256 channels) may have a greater pitch, such as a pitch between 50 μm to 75 μm, and electrical traces or connections for the respective channels. In order to minimize the attenuation of radiation that passes through the packaging structure before impinging on the sensor material, in certain implementations low-atomic number materials and/or thin thicknesses may be used in forming the packaging structure. As such, organic, such as polyimide, and non-inorganic materials, such as Teflon, may be used to form the flexible substrate. Likewise, as discussed herein, graphite, aluminum, or copper may be used in forming electrical interconnect structures or interfaces, such as in combination with an epoxy material, between the detector elements 72 and downstream readout circuitry. Likewise, anisotropic conductive film or other compressive adhesives may be used in forming the electrical connections between the detector elements 72 and interconnect features, as discussed herein.

The detector module 70 may also include or incorporate one or more application-specific integrated circuits (ASICs) 78 for reading out or otherwise operating the detector elements 72. In certain embodiments, an ASIC 78 may be provided on a flex circuit while in other embodiments, the flex circuit may be provided as part of a printed circuit board (PCB) in electrical communication with the detector elements 72. The ASIC 78 may be configured or designed to support a number of channels corresponding to the number of detector elements 72, such as 64 channels, 128 channels, or 256 channels. Likewise, an ASIC 78 may be provided as a one-dimensional or two-dimensional array.

In operation, the generalized detector module 70 of FIG. 4 may operate by generating electrical signals at the detector elements 70, where the signals correspond to or otherwise represent the amount of incident radiation (e.g., X-rays or gamma rays) at each detector element 70. The signal generated by each detector element 70 is read out via respective channel (i.e., electrical interconnect structure) connecting each respective detector element to a respective interface on the ASIC 78. The electrical interconnect structures (i.e., channels) may be provided on a flex circuit or other substrate 76 (e.g., a PCB) and the respective ASIC 78 and/or detector elements 72 may also be provided on or connected to the substrate 76. In certain embodiments discussed herein, such as anode-illuminated embodiments, the radiation detected by the detector elements 72 may pass through and be attenuated by portions of the detector package (i.e., structural and/or electrical features of the detector module 70 that do not actively participate in the direct conversion or detection of the radiation) such as electrical interconnects, flex circuitry, and so forth. As discussed in the embodiments below, these features or structures may be constructed so as to reduce or minimize the attenuation of radiation prior to the radiation reaching the detector elements.

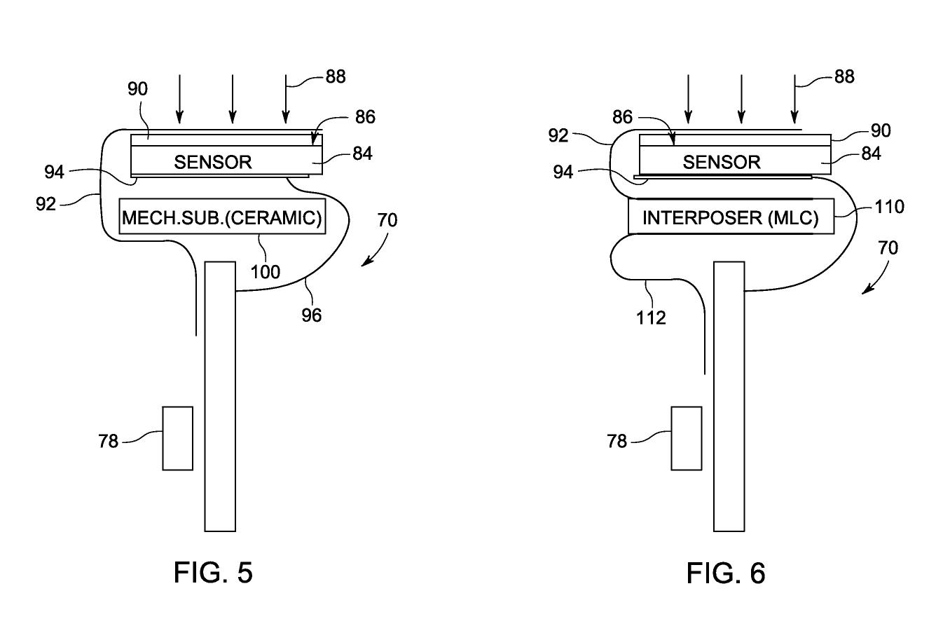

For example, turning to FIG. 5, an embodiment of an anode-illuminated detector module 70 is depicted. In this embodiment, the radiation-facing surface of the detector elements 72, generalized as sensor component 84, is depicted. In one such embodiment, a pixilated surface 86 of the sensor component 84 faces the transmitted or emitted radiation 88 and is in electrical contact with an anode electrode 90. The anode electrode 90 in turn is electrically connected (such as via a flex circuit including conductive traces, connections, or wires 92) to downstream readout circuitry, such as ASIC 78. The ASIC 78 may be electrically connected to the flexible circuitry itself or to a connect circuit board.

In the depicted embodiment, a surface of the sensor component 84 opposite the pixilated surface 86 is in contact with a continuous electrode 94 (such as a high-voltage continuous electrode) which allows application of a bias voltage to the sensor component 84, allowing readout of the detector elements 72 of the sensor component 84. The continuous electrode 94 is also electrically connected (such as via conductive wire, traces, or connections 96) to the downstream circuitry or substrates. In the depicted embodiment, the sensor component 84, along with anode 86 and continuous electrode 94, is mounted or situated on a mechanical substrate 100, such as a ceramic substrate, which may provide mechanical support for the assembly.

Turning to FIG. 6, an alternative embodiment is depicted in which an interposer 110 (such as a multi-layer ceramic interposer) is employed as an intermediary structure between the sensor component 84 (in which the pixilated surface 86) faces the direction of radiation 88 emission or transmission) and other electrical interconnections. The interposer 110 may in turn be electrically connected to a substrate, such as via conductive wire, traces, or connections 112. As will be appreciated, such an interposer 110 may provide an electrical interface for routing between one type of socket or connection to another, such as spread the connection to a wider pitch or to otherwise provide a physical rerouting from one layout to another connection or layout type. In certain such embodiments the interposer 110 may be combined with and/or act as a mechanical substrate as well as providing the interposer functionality. In other embodiments the functions of the mechanical substrate may be provided by a separate structure, such as the mechanical substrate 100, to which the interposer 110 is directly or indirectly connected.

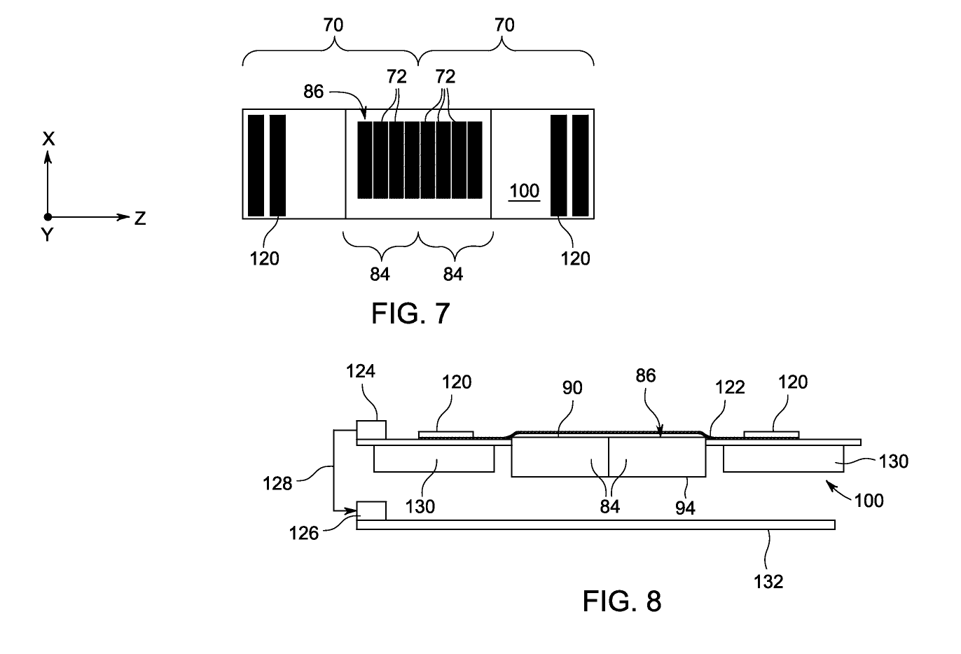

Turning to FIGS. 7 and 8, these figures depict a plan view and side schematic view, respectively, of a further embodiment. In the depicted plan view of FIG. 7, the pixilated surface 86 of two respective detector modules 70 that are packaged together faces upward (i.e., in the direction from which radiation approaches the detector module 70) and the respective detector elements 72 are affixed to a mechanical substrate 100. In one implementation, the detector modules 70 in combination have 20 rows of detector elements 72, providing approximately 14 mm of physical coverage, which may equate to 8 mm of coverage at isocenter.

In one implementation, and as depicted in FIG. 8, anodes 90 are provided on the pixilated surface 86 of the sensor component 84 at the locations of the detector elements 72 such that incident radiation passes through the anode 90 (and any associated electrical interconnect and/or flex circuit materials, prior to reaching the pixilated sensor component 84. The choice of low-atomic-number and thin thickness dimensions for the anode 90 and interconnect structure help to reduce the loss of radiation due to absorption before reaching the sensor material. In the depicted embodiment, electrical connection structures 120, such as multi-pin connectors, are provided on the substrate 100 such that respective electrical interconnects (i.e., channels) used to readout the detector elements 72 of the respective detector modules 70 are connected to respective locations or contact points on the respective electrical connection structures 120. For example, in one embodiment, the 32, 64, or 128 channels might connect the respective detector elements 72 of each detector module 70 to the respective electrical connection structure 120. Detector signals read out via the respective channels and electrical connection structures may then be acquired and/or processed by electrically connected circuitry, such as an ASIC.

Turning to FIG. 8, a schematic of a side view of the detector modules 70 of FIG. 7 is depicted. In this side view, anodes 90 are depicted as being in contact with the pixilated surface 86 of the sensor components 84. In the depicted implementation, the anodes 90 may be in electrical contact with a flexible circuit or connector 122, such as a high density flexible substrate having a flex thickness from 15-50 microns and conductor trace pitch of about 60 μm or less (e.g., 25 μm). A continuous or common electrode 94, such as a high voltage electrode, is positioned on the opposing surface of the sensor components 84 relative to the anodes 90. In the depicted embodiment, the anodes 90 are in electrical contact with the electrical connection structures 120, which in turn may be electrical contact with the additional contact structures 124 for aggregating or relaying signals acquired by the sensor components 84 to downstream circuitry. In one embodiment, rails 130, such as stainless steel rails, may be used to mount certain of the above structures, such as electrical connection structures 120, to the substrate 100, thereby accommodating for height differences among the components mounted on the substrate 100 and reducing vertical stress in the depicted flex circuit 122 material.

In the depicted example, the connector 124 is electrically connected (such as via wire, trace, or other electrical connection 128) to a corresponding connector 126 of an interface board 132 for the detector modules 70, such as a high density interface board. The electrical connection 128 may allow digital communication of signals generated by the readout ASIC components 120 to the interface board 132, may provide power from the interface board to the detector modules 70, and/or may provide a ground connection for the detector modules 70.

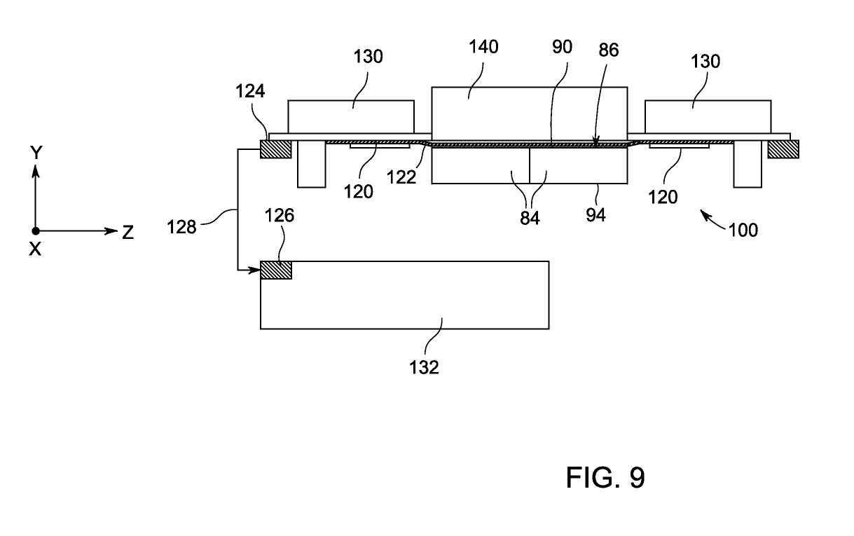

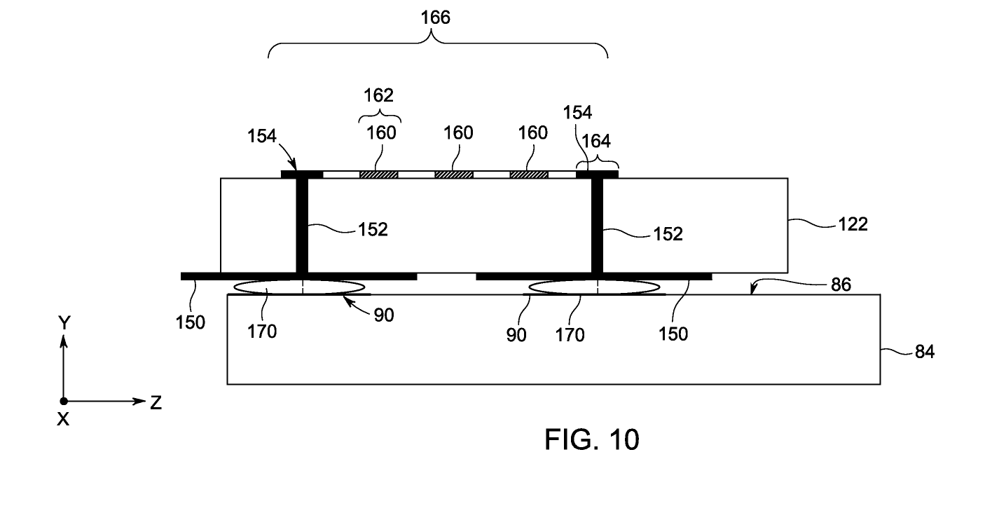

Turning to FIG. 9, a similar embodiment to that shown in FIG. 8 is depicted. The embodiment of FIG. 9, however, includes the addition of a collimator 140 that acts to collimate radiation impacting the sensor components 84. Such collimation may be useful in the context of CT imaging applications as well as SPECT imaging applications.

Turning to FIG. 10, a close-up of one implementation of the interconnections between the flexible circuit 122 and the sensor components 84 is depicted. As depicted in this implementation, a plurality of anodes 90 are present on the sensor component, such as one anode 90 per detector element 72 of the sensor component 84 such that an array of anodes 90 are present. The anodes 90 may be formed from a suitable conductive material and may, in some embodiments be a conductive material having a relatively low atomic number, low density, and or thin thickness to reduce or minimize the attenuation prior to the radiation reaching the sensor component 84. In one embodiment, the anodes 90 may be formed using aluminum, indium or copper instead of nickel, gold, or silver.

A flexible circuit 122 is depicted as overlying the sensor component 84 (i.e., in the path of the radiation). In one embodiment the flexible circuit 122 is formed from one or more layers of a polyimide film, such as a Kapton® film, or other suitable flexible material and has a thickness between about 15 μm and about 50 μm, such as about 25 μm. On the surface of the flexible circuit 122 facing the sensor component 84, respective interconnect pads 150 may be formed at locations corresponding to the anodes 90 on the surface of the sensor component 84. In one embodiment, the interconnect pads 150 may be formed from a low atomic number material, such as aluminum or copper, or may be of low density or of reduced thickness so as to have minimal attenuating effect of radiation passing through the flexible circuit 122 prior to reaching the sensor component 84. In one embodiment, the interconnect pads 150 have a length in the z-direction and x-direction between about 200 μm and about 300 μm.

In the depicted embodiment, the interconnect pads 150 are electrically connected (such as by vias 152) to via pads 154 to the opposing surface of the flexible circuit 122. The respective via pads 154 may in turn be electrically connected via features or traces 160 formed on the surface of the flex circuit 122. In the depicted example, the pitch of the flexible circuit 122 in the x-direction (i.e., x-pitch 166) is the distance from the middle of one via pad 154 to the next (i.e., the period by which via pads 154 are repeated), which determines the number of traces 160 that can be routed on the surface of the flex circuit 122 between the via pads 154. The x-pitch, p, may be given as:

p=(2n−1)w+D (1)

where n is the number of rows of via pads 154 (and, presumably, anodes 90 and detector elements 72), w is the width 162 of each trace 160, and D is the width 164 of each via pad 154.

In one embodiment, where the interconnect structures are formed at high density, the trace width 162 (i.e., w) may be between about 15 μm to about 50 μm, such as about 30 μm, the via pad width 164 (i.e., D) may be about 100 μm, and the pitch of the flexible circuit 122 in the z-direction may be about 700 μm. In such embodiments, the x-pitch (i.e., p) and number of rows (i.e., n) with respect to a CdTe/CdZnTe sensor component may be related as given in Table 1:

TABLE 1

CdTe/CdZnTe Piece

| X-pitch | # of | Physical z- |
|---|---|---|
| (μm) | Rows | dimension (mm) |
| 300 | 3 | 2.1 |
| 400 | 5 | 3.5 |
| 500 | 7 | 4.9 |
| 600 | 8 | 5.6 |
| 700 | 10 | 7 |
| 800 | 12 | 8.4 |
| 900 | 13 | 9.1 |
| 1000 | 15 | 10.5 |

Turning now to the interconnection between the flexible circuit 122 and the sensor component 84, in one implementation the interconnect pads 150 and anodes 90 are electrically connected by an electrically conductive connection material 170 disposed between each interconnect pad 150 and respective anode 90. The connection material allows electrical signals to pass from an anode 90 to the respective interconnect pad 150 and, from there, to downstream circuitry. In one implementation, the connection material may be an isotropic conductive adhesive, such as an epoxy material containing graphite particles, as opposed to nickel, silver, or gold particles. In such an implementation, the epoxy material may be dispensed or to a screen printed onto the interconnect pads 150 of the flexible circuit 122. The sensor component 84 may then be aligned and placed in contact with the flexible circuit 122 such that each anode 90 is electrically connected with a corresponding interconnect pad 150 of the flexible circuit 122. The epoxy material may then be cured at a suitable temperature, such as at a temperature from about 25 C to about 120 C.

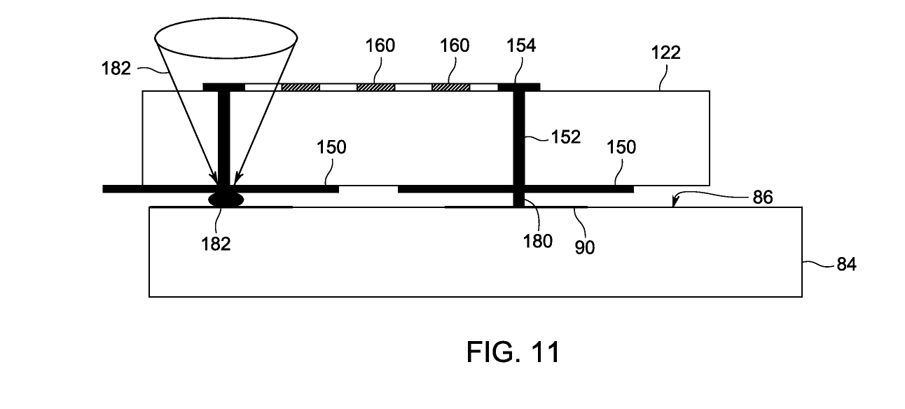

Turning to FIG. 11, in a further implementation, the interconnection between the interconnect pads 150 of the flexible circuit 122 and the anodes 90 of the sensor components 84 may be formed using focused laser energy. For example in one such implementation the traces, 160, via pads 154, vias 152, and interconnect pads may all be initially formed as part of the flexible circuit 122 (such as within or on a polyimide layer forming the substrate of the flexible circuit 122). Material 180 at the interface of each interconnect pad 150 and anode 90 may be subjected to focused laser energy 182 to heat and melt the material 180, forming a contact point 182 between each interconnect pad 150 and anode 90.

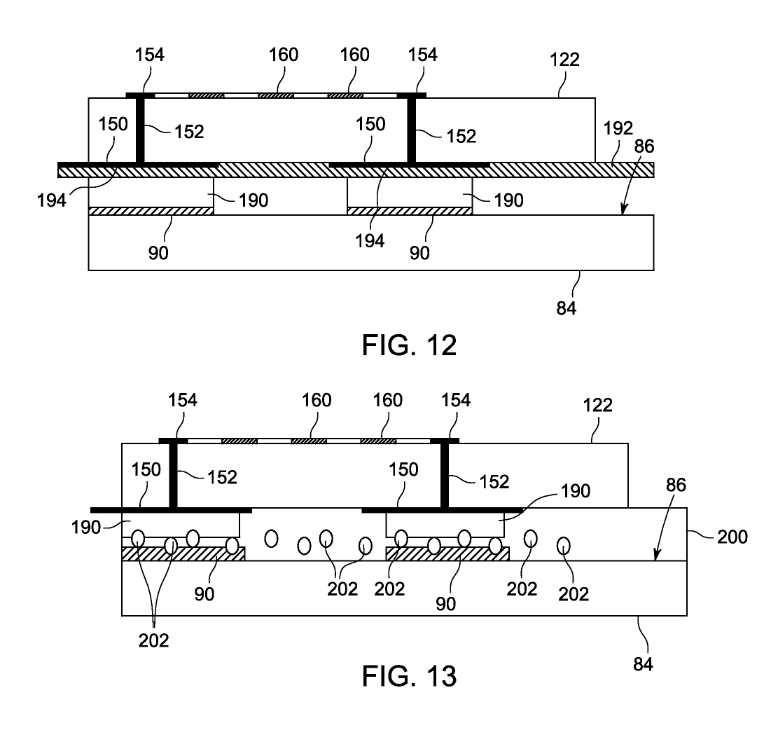

In a further embodiment, FIG. 12 depicts another interconnect approach. In the depicted approach, a conductive bump or pillar 190 may be applied to one of the anodes 90 and/or interconnect pads 150. An electrically non-conductive adhesive 192 may be used to adhere or secure the flexible circuit 122 (and associated interconnect pads 150) to the respective sensor component 84 (and associated interconnect pads 150). Thus, as formed, the non-conductive adhesive layer initially separates the conductive bumps or pillars 190 and the corresponding conductive structures on the complementary structure, such as the interconnect pads 150. In one embodiment, the non-conductive adhesive 192 is cured or compressively displaced (such as by application of pressure) such that the layer of non-conductive adhesive 192 is thinned or shrunk and the conductive bumps or pillars 190 and the complementary conductive structures are brought into contact. For example, in the depicted embodiment, a bump 194 formed on the interconnect pads 150 may extend through the non-conductive adhesive 192 when the non-conductive adhesive is compressed or cured, thereby allowing the bump 194 to contact the bump or pillar 190 formed on the anodes 90 of the sensor component 84.

In another implementation (and as depicted in FIG. 13), an anisotropic conductive film 200 may be used to adhere the flexible circuit 122 to the sensor component 82. Such an anisotropic conductive film 200 may be applied and/or set using heat and/or pressure to bond the respective sensor component 84 and flexible circuit 122 together. In one such implementation, conductive bumps or pillars 190 may be formed on the anodes 90 and/or interconnect pads 150 but the conductive bumps or pillars 190 are still separated from direct contact with the complementary conductive structure by the anisotropic conductive film 200. In such an implementation, the anisotropic conductive film 200 may include conductive particles 202 that are smaller than the interconnect distance (i.e., the distance between the interconnects pads 150 and the anodes 90) but large enough to conductively connect the bumps or pillars 90 and the complementary conductive structures (such as the depicted anodes 90).

Technical effects of the invention include the formation and use of anode-illuminated direct conversion radiation detectors. In one embodiment, the anodes of a sensor element are electrically connected to an interconnect structure (e.g., a flex circuit) using an epoxy material that may include graphite or other low atomic number conductive particles. In another embodiment, the anodes of the sensor element are electrically connected to the interconnect structure by laser-formed contact structures. In a further embodiment, the anodes of the sensor element are electrically connected to the interconnect structure using a non-conductive adhesive that is cured or compressively displaced so as to allow electrical connection between conductive bumps or pillars formed on the anodes and/or interconnect pads and the complementary conductive structures. In an additional embodiment, the anodes of the sensor element are electrically connected to the interconnect structure using an anisotropic conductive film or adhesive that includes conductive particles that allow electrical connection between conductive bumps or pillars formed on the anodes and/or interconnect pads and the complementary conductive structures

This written description uses examples to disclose the invention, including the best mode, and also to enable any person skilled in the art to practice the invention, including making and using any devices or systems and performing any incorporated methods. It should also be understood that the various examples disclosed herein may have features that can be combined with those of other examples or embodiments disclosed herein. That is, the present examples are presented in such as way as to simplify explanation but may also be combined one with another. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A radiation detector, comprising:
a plurality of detector elements comprising a direct conversion material that generates electrical signals directly in response to incident radiation;
a respective anode for each detector element, wherein each anode is positioned over the respective detector element such that incident radiation passes through the anode before reaching the respective detector element;
a flexible circuit structure comprising aluminum or copper interconnect pads in electrical contact with the anodes, wherein the flexible circuit structure comprises one or more layers of a polymeric composition; and
an interconnect structure electrically connecting the respective anodes and the flexible circuit structure;

2. The radiation detector of claim 1, wherein the plurality of detector elements are formed from one of cadmium telluride, cadmium zinc telluride, gallium arsenide, or mercury iodine.

3. The radiation detector of claim 1, comprising an application-specific integrated circuit in communication with the plurality of detector elements via the flexible circuit structure.

4. The radiation detector of claim 1, comprising a mechanical substrate on which the plurality of detector elements are mounted.

5. The radiation detector of claim 1, comprising an interposer for routing between one type of electrical socket or connection to another.

6. The radiation detector of claim 1, comprising a continuous electrode disposed on a surface of the plurality of detector elements opposite the respective anodes.

7. The radiation detector of claim 1, comprising a collimator configured to collimate the incident radiation prior to the incident radiation reaching the plurality of detector elements.

8. The radiation detector of claim 1, wherein the plurality of anodes are formed from copper or aluminum.

9. The radiation detector of claim 1, wherein the flexible circuit structure has a thickness between about 15 μm and about 40 μm.

10. The radiation detector of claim 1, wherein the interconnect structure comprises an epoxy material containing graphite particles.

11. The radiation detector of claim 1, wherein the interconnect structure comprises laser-formed contact points.

12. The radiation detector of claim 1, wherein the interconnect structure comprises a non-conductive adhesive through which conductive contacts are formed when the non-conductive adhesive is thinned or shrunk.

13. The radiation detector of claim 1, wherein the interconnect structure comprises an anisotropic conductive film that includes conductive particles.

14. The radiation detector of claim 1, wherein the one or more layers of the polymeric composition have a flex thickness of 60 μm per layer or less.

15. A method for forming a radiation detector, comprising:
forming an aluminum or copper anode on each of a plurality of detector elements, wherein each detector element comprises a direct conversion material that generates electrical signals directly in response to incident radiation;
electrically connecting the respective anodes and respective aluminum or copper interconnect pads of a flexible circuit structure comprising one or more layers of a polymeric composition; and
electrically connecting the flexible circuit structure to readout circuitry suitable for acquiring signals from the plurality of detector elements.

16. The method of claim 15, wherein electrically connecting the respective anodes and respective aluminum or copper interconnect pads comprises applying an epoxy material containing graphite particles between each anode and respective interconnect pad.

17. The method of claim 15, wherein electrically connecting the respective anodes and respective aluminum or copper interconnect pads comprises laser-forming respective contact points between each anode and respective interconnect pad.

18. The method of claim 15, wherein electrically connecting the respective anodes and respective aluminum or copper interconnect pads comprises applying a non-conductive adhesive layer or an anisotropic conductive film between the flexible circuit structure and the plurality of detector elements.

19. An imaging system, comprising:
a direct conversion radiation detector, the radiation detector comprising one or more detector modules that each comprise:
a plurality of detector elements that generates electrical signals directly in response to incident radiation;
a flexible circuit structure comprising aluminum or copper interconnect pads each in electrical contact with an anode disposed in the radiation path of a respective detector element, wherein the flexible circuit structure comprises one or more layers of a polymeric composition; and
an interconnect structure electrically connecting the respective anodes and the flexible circuit structure;
a data acquisition system in communication with the radiation detector; and
a controller controlling operation of the data acquisition system.

20. The imaging system of claim 19, wherein the interconnect structure comprises an epoxy material containing graphite particles

21. The imaging system of claim 19, wherein the interconnect structure comprises laser-formed contact points.

22. The imaging system of claim 19, wherein the interconnect structure comprises a non-conductive adhesive layer or an anisotropic conductive film disposed between the flexible circuit structure and the plurality of detector elements.
